(19) United States
(12) Patent Application Publication
(10) Pub. No.: US 2002/0121702 A1
(43) Pub. Date: Sep. 5, 2002

(54) Method and structure of in-situ wafer scale polymer stud grid array contact formation

(75) Inventor: Leo M. Higgins III, Austin, TX (US)

Correspondence Address: SCHIFF HARDIN & WAITE, 6600 SEARS TOWER, 233 S WACKER DR, CHICAGO, IL, 60606-6473, US

(73) Assignee: Siemens Dematic Electronics Assembly Systems, Inc.

(21) Appl. No.: 10/085,224

(22) Filed: Feb. 28, 2002

Related U.S. Application Data
(60) Provisional application No. 60/272,520, filed on Mar. 1, 2001.

(51) Int. Cl. H01L 23/48; H01L 23/52

(52) U.S. Cl. 257/758; 257/743; 257/751; 438/618; 438/623; 438/622

(57) ABSTRACT

Methods and structures of in-situ wafer scale polymer stud grid array (ISWS-PSGA) contact formation on integrated circuit devices, wherein a separate pre-manufactured PSGA substrate is not needed. The methods include injection molding of thermoplastics, transfer-molding of thermoset materials, lamination of polymer films with subsequent in-situ molding/embossing, and forming the PSGA structure directly on the semiconductor wafer. The ISWS-PSGA structure extends across the entire semiconductor wafer, with ISWS-PSGA metallized input/output studs disposed across each of the integrated circuit devices on the wafer. The polymer formed on the wafer surface to create the stud field is extended beyond the perimeter of the wafer, and the polymer film extension is used for temporary connection to an integrated circuit tester, or an integrated circuit test/burn-in system. The extension may further include studs for contacting the tester.

### REFERENCE TO PROVISIONAL APPLICATION

This application claims benefit to U.S. provisional application 60/272,520 filed Mar. 1, 2001, which is incorporated herein by reference.

### BACKGROUND OF THE INVENTION

1. Field of the Invention

The present invention is generally directed to polymer stud grid arrays (PSGAs). In particular the present invention is directed to methods of forming in-situ wafer scale polymer stud grid arrays (ISWS-PSGAs), and structures formed using the methods.

2. Discussion of the Related Art

Wafer level packaging is in high demand due to miniaturization benefits. Formation of input/output (I/O) features on integrated circuit (IC) devices while still in wafer form is very desirable, since it allows for simpler IC-level testing and lower cost testing. In addition, wafer level packaging is more efficient because it eliminates packaging of each individual IC after wafer dicing. Moreover, the need for “assembly” packaging processes is eliminated.

Wafer level test/burn-in is very efficient versus individual die test/burn-in when it comes to producing a Known Good Die (KGD). Because testing of individual bare die, or packaged die, requires numerous and costly testers and handlers, which spend a majority of time moving and handling the devices. In addition, bare IC or packaged component burn-in requires large areas, many testers, many sophisticated heated chambers, specialized equipment, and many expensive high temperature printed circuit boards and sockets.

Several competitive wafer level packaging methods and products are on the market at this time, most of which, if not all, use lead-tin solder balls for the I/O connection.

Wafer level polymer stud grid array (PSGA) provides the benefits mentioned above, plus benefits unique to PSGAs, such as lead-free fabrication, damage resistant I/O pads, stress compliant I/O for higher second level interconnect reliability, and contamination-free contact in testing, etc. In addition, the PSGA structure is formed directly on the semiconductor wafer. Thus, there is no need to pre-manufacture or use a separate PSGA substrate.

Several methods of forming the PSGA structure on the semiconductor wafer, and optional extension regions, are possible. Such methods include injection molding of thermoplastics, transfer molding of thermoset materials, and the lamination of a film to the wafer using tooling to raise or emboss the studs into the film surface during lamination.

Two versions of ISWS-PSGA are described herein. In a first version, the PSGA field extends across the entire semiconductor wafer, with the PSGA input/output (I/O) studs disposed across each of the individual IC device areas. I/O studs are studs which have been metallized and connected to PCMs. In a second version, the polymer formed on the semiconductor wafer surface to create the stud field is extended beyond the perimeter of the wafer. This polymer film extension is used for temporary connection to the IC tester, or an IC test/burn-in system. This extension may have studs for use in making contact to the tester, although other stud-free ways of connection to the tester are conceivable.

### SUMMARY OF THE INVENTION

In accordance with one aspect of the present invention, a method for forming an in-situ wafer scale polymer stud grid array, the method comprising providing a semiconductor wafer with integrated circuit device areas, the integrated circuit device areas having exposed bond pads and wafer passivation, and applying one or more metal film depositions over the bond pads and the wafer passivation; patterning the one or more metal film depositions extending over the exposed bond pads and the wafer passivation to create metal film segments in desired locations over the bond pads to perform as bond pad cover metallurgy; coating the semiconductor wafer with a first polymer layer processed to form raised studs having stud tip contacts in desired locations on the surface of each of the integrated circuit device areas; removing regions of the first polymer layer to expose a central portion of underlying bond pad cover metallurgy; processing the first polymer layer to clean and prepare the exposed central portion of the underlying bond pad cover metallurgy for adhesion to subsequently applied metal layers; processing the first polymer layer for high conductor adhesion; applying a metal coating to the semiconductor wafer to cover at least all exposed pad cover metallurgy areas and all exposed regions of the first polymer layer; thickening the metal coating and forming an interconnect circuit thereon; forming a second polymer layer over selected areas of the metal coating; and depositing a barrier layer and an oxidation protection layer on exposed areas of the metal coating.

In accordance with another aspect of the present invention, a method for forming an in-situ wafer scale polymer stud grid array on a semiconductor wafer having integrated circuit device areas, the integrated circuit device areas having patterned pad cover metallurgy regions, exposed bond pads and wafer passivation, the method comprising applying one or more metal film depositions over the exposed bond pads and the wafer passivation; processing the one or more metal film depositions extending over the exposed bond pads and the wafer passivation across the semiconductor wafer to create metal film segments in desired locations over the exposed bond pads to perform as bond pad cover metallurgy; placing the semiconductor wafer in a tooling plate which provides an annular ring region about the wafer, wherein one surface of the annular ring region is substantially coplanar with the surface of the wafer; coating the semiconductor wafer and a desired portion of the surface of the tooling plate annular ring region with a first polymer layer processed to form raised studs at desired locations across the surface of each of the integrated circuit device areas; removing regions of the first polymer layer to expose a central portion of underlying bond pad cover metallurgy; processing the semiconductor wafer to clean and prepare the exposed central portion of the underlying bond pad cover metallurgy for adhesion to subsequently applied metal layers; processing the first polymer layer for high conductor adhesion; applying a metal coating over the semiconductor wafer and the annular ring region of the surrounding tooling plate surface covering at least all exposed pad cover metallurgy areas and all exposed regions of the first polymer layer; coating the active surface of the semiconductor wafer with one or more metal films; thickening the metal coating and forming an interconnect circuit thereon; forming a second polymer layer over selected areas of the metal coating and selected regions of the exposed first polymer layer; and depositing a barrier layer and an oxidation protection layer on exposed areas of the metal coating, and forming a circuit pattern about the semiconductor wafer that is contiguous with desired circuit elements in the metal coating across the active wafer surface and the annular ring region of the tooling plate.

In accordance with a further aspect of the present invention, an in-situ wafer scale polymer stud grid array structure formed directly on a semiconductor wafer having individual integrated circuit device areas and connecting bond pads thereon, the polymer stud grid array structure comprising raised studs in desired locations formed across the surface of each of the integrated circuit device areas; exposed bond pad cover metallurgy central portions; one or more metal film depositions covering connecting the bond pads and the raised studs; a metal layer covering the semiconductor wafer processed to connect desired pad cover metallurgy central portions with studs to form a desired interconnection circuit; and a polymer layer covering the desired regions of the entire circuit area, such that a barrier layer and an oxidation protection layer of metal covers the exposed metal features, the grid array extending across the entire semiconductor wafer, and metallized studs being disposed across each of the integrated circuit device areas.

In accordance with a further aspect of the present invention, an in-situ wafer scale polymer stud grid array structure comprising a semiconductor wafer having individual integrated circuit device areas and patterned pad cover metallurgy regions, and coated with a first polymer layer processed to form raised studs in desired locations across the surface of each of the integrated circuit device areas; exposed bond pad cover metallurgy central portions; a metal layer covering the semiconductor wafer process to connect desired pad cover metallurgy central portions with studs to form a desired interconnection circuit; and a second polymer layer covering the entire interconnection circuit area, such that a barrier layer and an oxidation protection layer of metal covers the exposed metal features, the grid array field extends across the entire semiconductor wafer, and metallized studs are disposed across each of the integrated circuit device areas, the circuit pattern in the film material coating the surface of the annular ring region about the semiconductor wafer is contiguous with desired circuit elements in the material coating the surface of the semiconductor wafer, and the interconnection circuit area extends beyond the edge of the semiconductor wafer.

These and other aspects of the invention will become apparent after careful review of the following detailed description of the presently preferred embodiments and accompanying drawings.

### BRIEF DESCRIPTION OF THE DRAWINGS

FIG. 1 shows a region of a semiconductor wafer with devices having a perimeter array of input/output bond pads, in accordance with an exemplary aspect of the present invention;

FIG. 2A shows an active device surface of a semiconductor wafer, in accordance with an exemplary aspect of the invention;

FIG. 2B shows detailed schematic plan view of a field of studs on portions of a polymer coated semiconductor wafer, in accordance with an exemplary aspect of the present invention;

FIG. 3 shows a detailed schematic plan view of a region of a semiconductor wafer after polymer coating and formation of PSGA studs, in accordance with an exemplary aspect of the present invention;

FIG. 4A shows a detailed schematic plan view of a region of a semiconductor wafer after metallization and patterning of metal conductors to connect PCM pads with desired studs, in accordance with an exemplary aspect of the present invention;

FIG. 4B shows a detailed schematic plan view of a conductor metallization pattern which links PCM pads and studs on an individual integrated circuit region, in accordance with an exemplary aspect of the present invention;

FIG. 5 shows a detailed schematic cross sectional view of bond pad-stud region after in-situ forming of polymer coating and polymer stud and metallization processes, in accordance with an exemplary aspect of the present invention; and

FIGS. 6A and 6B show detailed schematic cross-sectional views of an in-situ polymer stud grid array, in accordance with another exemplary aspect of the present invention.

### DETAILED DESCRIPTION OF THE PRESENTLY PREFERRED EMBODIMENTS

A general process flow description of exemplary embodiments of the present invention will now be given with respect to a semiconductor wafer. Bond pads (typically aluminum, but copper is beginning to be more common) formed on the wafers are coated to prevent high contact resistance and corrosion in subsequent fabrication steps, environmental testing, or in application environments. This coating is called pad cover metallurgy (PCM).

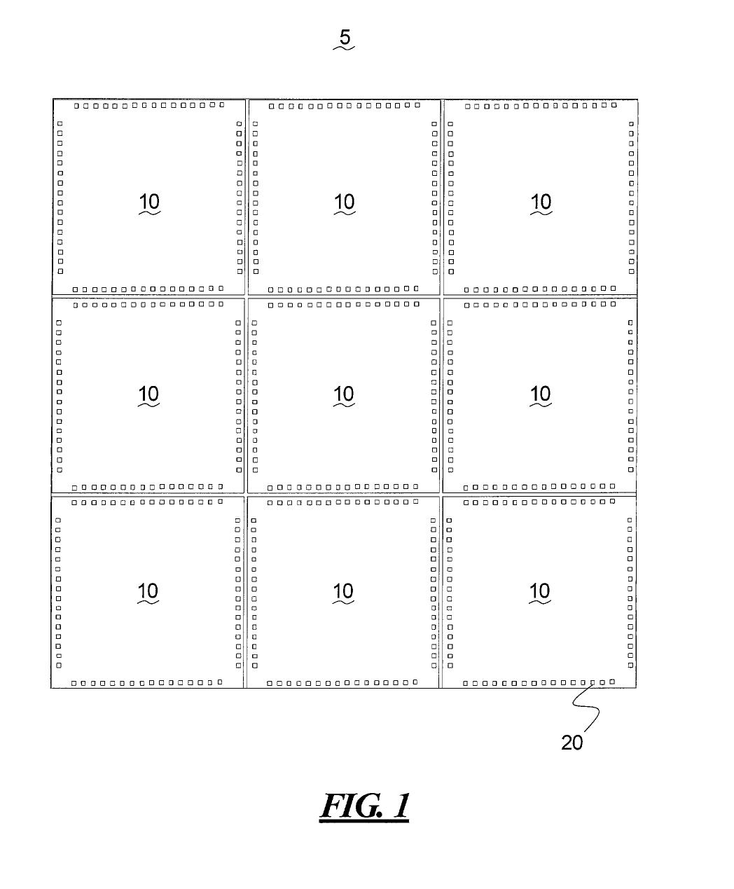

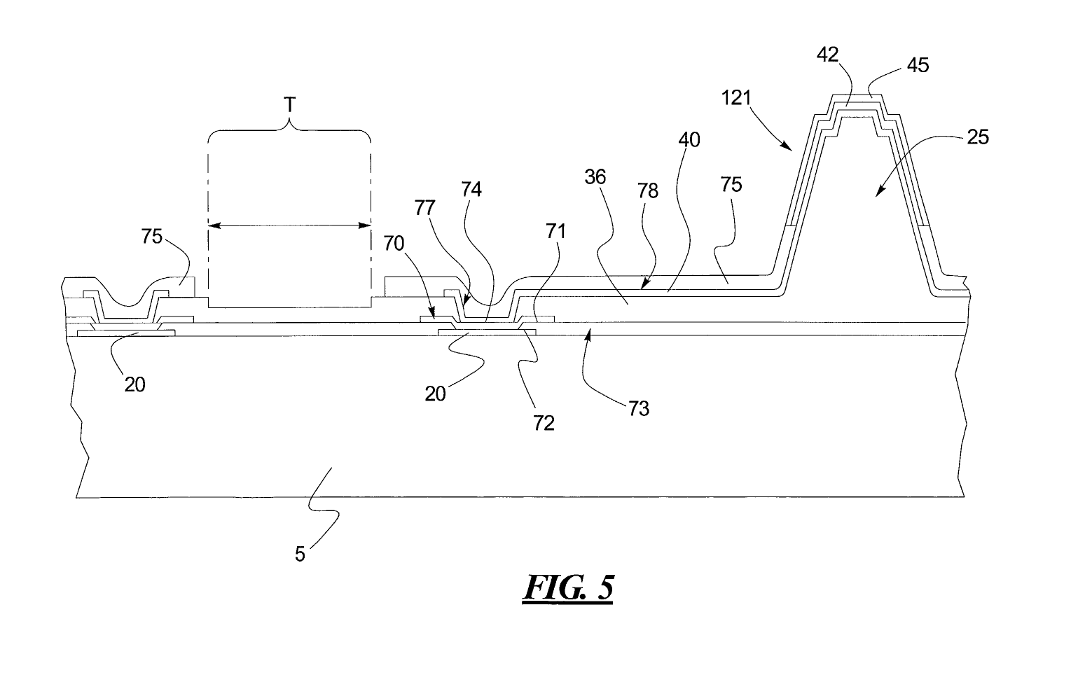

FIG. 1 shows a detailed plan view of a segment of a region of the IC wafer 5 having nine integrated circuit (IC) devices 10. Each IC device 10 has a perimeter array of coated input/output (I/O) bond pads 20, which are also shown in cross section in FIG. 5. Perimeter bond pad 20 locations are illustrated, but it is within the scope of this invention to include bond pads disposed in any location across the area of IC devices 10.

The PCM coating 70, shown in cross section in FIG. 5, on the pads 20 may include electroless nickel and gold; thin-film titanium and nickel and gold; thin film titanium and palladium; thin-film titanium/tungsten and gold; thin film titanium-titanium/tungsten/nitrogen-tungsten and gold; thin-film nickel-nickel/vanadium and gold; thin-film aluminum and nickel/vanadium and gold; thin-film chromium and chromium/copper and copper and gold, and the like. Use of a final gold, or other noble metal, layer may be optional since it is primarily an oxidation protection layer.

The PCM coatings 70 provide high adhesion to an Al or Cu pad 20 (shown in FIG. 5), provide a barrier to undesirable interdiffusion of atomic species; provide a low ohmic resistance contact to an Al or Cu pad 20, provide a low ohmic resistance to subsequently applied metallurgies 40 (shown in FIG. 5) used in the creation of the in-situ wafer scale polymer stud grid array (ISWS-PSGA). In addition, the PCM coatings 70 allow the total metal layer stack to resist corrosion, as well as prevent interface degradation due to excessive intermetallic embrittlement, electro-migration, and other stresses from environmental testing and the use environment.

The PCMs may also be formed by depositing electroless Ni to cover only the bond pads 20 and the perimeter passivation area, and then a thin gold layer via immersion gold plating or electroless gold plating is deposited only on the Ni surface. This type of process does not require patterning of the full wafer area film to create the desired PCMs.

Typically the pad-covering metallurgy 70 extends beyond the bond pads 20 somewhat, and covers the bordering surface 71 of wafer passivation 73, which may overlay the perimeter region 72 of the bond pad 20 metallurgy.

The metal film depositions over the bond pads 20 and the wafer passivation 73 is the first process performed on the wafer 5 in the flow to make the ISWA-PSGA. The metal film depositions over the bond pads 20 and the wafer passivation 73 is a blanket of one or more metal films that cover the entire desired active surface of the semiconductor wafer 5, except perhaps the outer 1 to 2 millimeters of the active surface perimeter. The one or more metal layers are photolithographically processed (coating with resist, exposing the resist through a phototool, developing the resist to remove all resist except where the resist covers the blanket layer of metal films in regions where formation of the PCMs 70 is desired, etching away exposed metal films, and striping specific resist patches leaving small PCM patches where the resist had been). The PCMs that remain covering the bond pads 20 are segments of the original one or more metal film depositions.

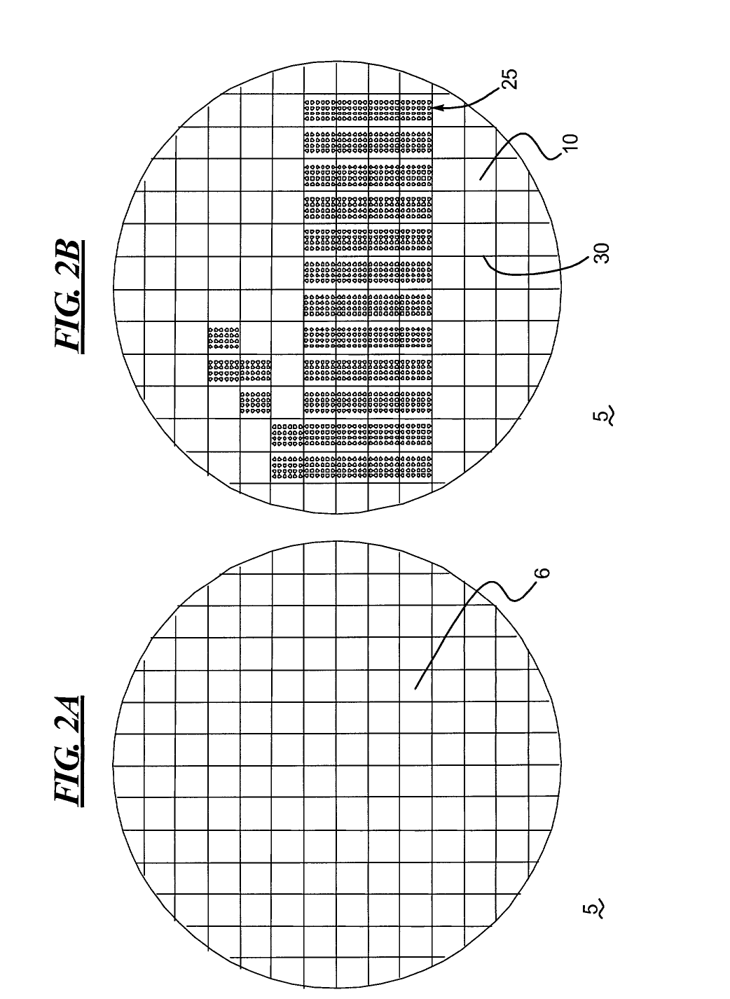

A first version of the exemplary embodiments of the present invention will now be discussed with respect to FIGS. 2A and 2B.

FIG. 2A shows a schematic plan view of a finished semiconductor wafer 5 shown in FIG. 1, showing active device surfaces 6, before coating with the polymer material 36 (shown in cross section in FIG. 5).

FIG. 2B shows a schematic plan view of a finished semiconductor wafer 5 shown in FIG. 1, showing the active device surfaces 6, after coating with the polymer material 36 and after formation of the studs 25. The view in FIG. 2B is before making openings to expose the central portion of the PCM and to clear polymer from the dicing paths or streets 30. The semiconductor wafer 5 is coated with a polymer material which is processed to form raised studs 25 across the surface of each IC device 10. Prior to coating, the polymer may be a solid (in the form of granules, pellets, or a film), a liquid, or a paste mixture of substantially solid phase(s) and substantially liquid phases(s).

In one embodiment, solid thermoplastic polymer system material, typically in the form of granules, may be a pure or mixed resin system, or may be comprised of said resin or mixed resin system and a filler material, and may be injection molded against the surface of the wafer using elevated temperatures and pressures. The resin may be selected from a group of polymers possessing the necessary properties which includes, but are not limited to liquid crystal polymer, polyetherimide, syndiotactic polystyrene, and the like. Mixed resin systems comprising co-polymers, polymer alloys, or blended polymers, and the like are also included in this invention. Filler materials that may be used in the invention may be selected from a group of particulate materials that possess the necessary properties which includes, but is not limited to crushed fused silica, spherical fused silica, crushed quartz, aramid particles, polytetrafluoroethylene particles, particles of similar fluorinated polymers, particles of low thermal expansion ceramic materials including lithium aluminosilicates, magnesium aluminum silicates, silica-encapsulated aluminum nitride, and the like.

In another embodiment of the invention solid thermoset polymer system material, typically in the form of pellets kept at low temperatures, typically −40° C., or less, before use may be a pure or mixed resin system, or may be comprised of said resin or mixed resin system and a filler material, and may be transfer molded against the surface of the wafer using elevated temperatures and pressures. The resin may be selected from a group of polymers possessing the necessary properties which includes, but is not limited to epoxy cresol novolac, and bi-phenyl epoxy based systems. Commercial examples of possible candidate materials include Sumitomo Bakelite EME-S351 LP, Nitto MP8000, Hitachi Chemical CEL 300, and other competitive products from Cookson/Plascon, Shin-etsu, and others. Filler materials that may be used in the invention may be selected from a group of particulate materials that possess the necessary properties which includes, but is not limited to crushed fused silica, spherical fused silica, crushed quartz, aramid particles, polytetrafluoroethylene particles, particles of similar fluorinated polymers, particles of low thermal expansion ceramic materials including lithium aluminosilicates, magnesium aluminum silicates, silica-encapsulated aluminum nitride, and the like.

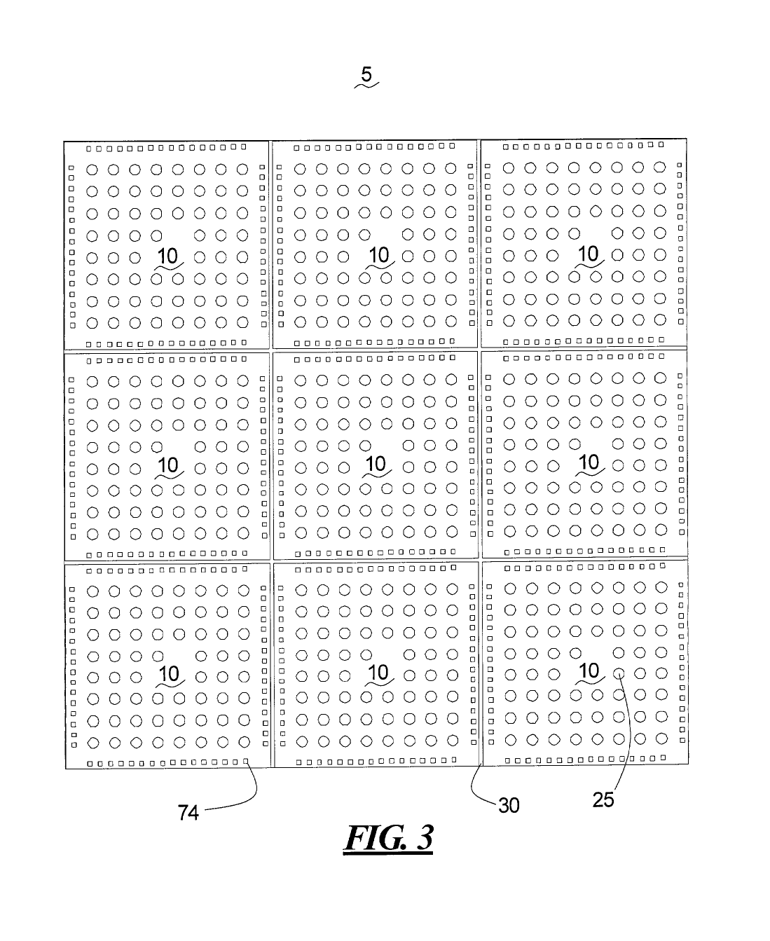

As shown in FIG. 5, during formation of the studs 25, the polymer coating 36 may also be formed to be thinner in the paths or streets 30 (shown in FIG. 3) between the individual IC devices 10 to minimize stress on the wafer 5, to improve dicing and to minimize stress due to thermal expansion differences between the wafer 5 and the polymeric coating 36.

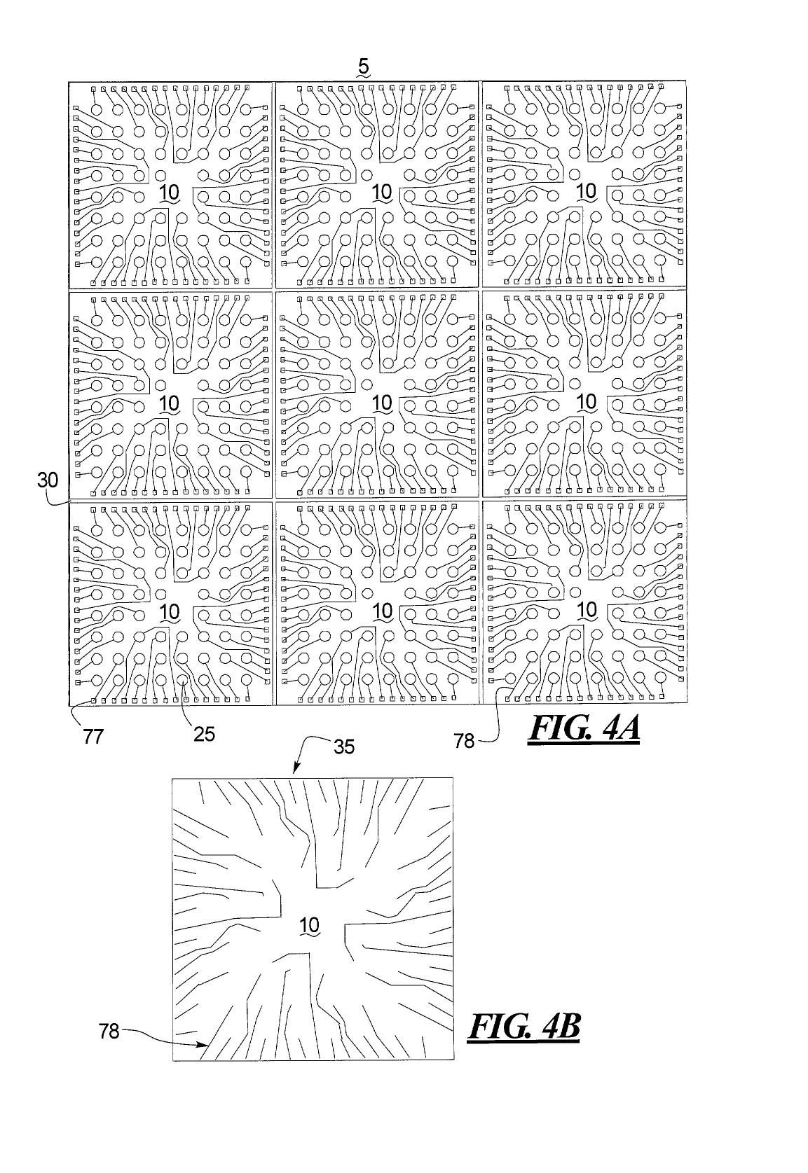

Polymer coating 36 is removed from the central region of the PCM 70, which covers bond pads 20, exposing the PCM 70 central portion 74. This exposed central portion 74 of the PCM 70 becomes the contact region, for contact pad 77 formed from the subsequently applied metal layer 40 (as shown in FIG. 4A, where the viewed surface is all polymer, except for the metallized contact pads, conductor patterns, and metallized stud surfaces, and also shown in cross section in FIG. 5). Removal of the polymer 36 may be by laser ablation, photolithography, reactive ion etching, plasma etching, or by other such methods. The polymer may also be removed from the paths 30 to be followed by dicing saw blades.

FIG. 3 shows a detailed schematic plan view of the semiconductor wafer 5 shown in FIG. 1, after formation of PSGA studs 25, the formation of openings in polymer 36 to expose the central portion 74 of PCM 70, and the removal of polymer 36 from the dicing streets 30.

The surface shown in FIG. 3 is all polymer 1, except the perimeter openings about each IC 10 which expose the central portions 74 of all the PCMs 70. The exposed PCM 70 central portions 74 across the entire wafer 5 are prepared for second phase metal deposition which is required to form the metallization which will electrically connect the exposed PCM central portion 74, which coats bond pads 20 with the studs 25. If the outer layer of the PCM is copper, the copper oxide will be removed from PCM 70 central portion 74, and the copper may be roughened by microetching. If the external metal layer of PCM 70 was gold, this cleaning step may include removal of this gold from the PCM 70 central portion 74. These could be wet processes (e.g. aqueous solution etching), or they could be dry processes (e.g. reactive ion etching, plasma etching, etc.). These processes would also be combined with processes to prepare the polymer 36 surface for high conductor adhesion.

The entire surface of the wafer 5 is then coated with a first metal (e.g. copper). This could be accomplished by sputtering (physical vapor deposition (PVD)), chemical vapor deposition/CVD, electroless plating, or by other methods, and combinations of these methods.

The first metal, here described as Cu, may then be thickened with additions of the same metal by various methods, including extended processing as described above, by electrolytic plating of added Cu thickness, by electroless plating of added Cu thickness, etc. The first metal may also function principally as an adhesion promotor, diffusion barrier, and cathode layer for subsequent plating to thicken the first metal. Thus the first metal may be thickened by the application of a dissimilar metal. The first metal may also comprise films of more than one metal, with each metal serving a different function. As an example, the first layer of the first metal may be a sputtered film of titanium to act as an adhesion promotor and diffusion barrier. The second layer of the first metal may be a sputtered film of copper to act as a low electrical resistance cathode plane for subsequent electroplating. The subsequent electroplating of copper, nickel, etc., would be performed to thicken the first metal to allow the conductors thus formed to acquire the desired electrical performance capabilities.

FIG. 3 also shows the perimeter openings in the polymer 36 coating exposing the central portions of the PCM, and perimeter streets 30 about each IC region 10 where the polymer coating is reduced in thickness.

FIG. 4A shows a detailed schematic plan view of the finished IC devices 10 of FIG. 1, with desired interconnect circuits 78 and contact pads 77 formed from the Cu layer by standard photolithographic, or other, processes. For instance, the Siemens Laser Structuring Process may be used, wherein a mask layer (typically Sn or thin polymer) is deposited on the Cu. The laser removes the mask material in desired areas, and possibly removing some portion of the Cu thickness, and then the exposed Cu is etched away, and the mask material is removed, leaving the desired interconnect circuit 78 and contact pads 77. If the IC devices 10 do not need to be bussed together for wafer level test or wafer level test and burn-in, or if wafer level test or wafer level burn-in is not planned for the devices 10, the Cu may also be removed from the saw paths 30.

The final polymer layer 75 is formed over the entire circuit area, except the stud tip contacts, saw paths 30, and any other desired contact pads (testing, etc.). The polymer layer may be formed by spin coating, spraying, dispensing, film lamination, etc. an added process step may be needed to remove the polymer from the desired areas. This may be accomplished via dry processing (reactive ion etching, plasma etching, laser ablation, etc.), by laser ablation, or by wet processes (etching, photolithographic processing, etc.).

In the case of photolithographic processing, the second polymer layer is expected to be a photo-imageable resist or solder mask which is normally exposed to light through a phototool and then developed in a wet process to remove the desired material and leave the permanent polymer behind in desired locations. This sequence of photolithography can also be followed in a more complex sequence where the second polymer coating is applied and fully cured. Then, the photo-imageable resist is applied—exposed—developed to leave material overlying the desired second polymer regions. The wafer may then be subjected to dry processing in a plasma or reactive ion etching (RIE). Here the plasma or RIE removes material from the surface everywhere, but the process requires the thickness of the resist overlying the desired second polymer areas to protect the underlying second polymer layer. Thus, the plasma or RIE removes second polymer layer material from undesired regions which were exposed to the plasma or RIE by the developing and removal of the resist in the previous operations. Then the thinned remains of the resist are removed from the surface of the desired second polymer areas, leaving the second polymer layer just where it was desired.

FIG. 4B shows a detailed schematic plan view of a conductor metallization pattern 35. The metallization pattern 35 also forms the desired contact pads 77 (shown in FIG. 4A) and covers the studs 25 (shown in FIG. 4A).

FIG. 5 shows a detailed schematic plan view of a cross-section through metallized studs 121, conductor pattern 78 segments, and contact pads 77 shown in FIG. 4A, after the in-situ forming of the final polymer coating 75 (the resist layer), formation of polymer studs 25, and all conductor 78 metallization processes. The contact pads 77 may be coated with a second polymer layer 75 so that the pads 77 are not plated with Ni and Au layers, 42, 45, respectively. Alternatively, if it is desired to probe or solder to contact pads 77, the second polymer layer could be removed from the area above contact pads 77, thereby allowing for Ni 42 and Au plating on the exposed Cu surface of the contact pads 77.

A conductor material is used which is an extension of the metal 40, which forms interconnection circuits 78. Thus, the interconnect circuits 78 that are on the individual ISWS-PSGA packaged units, would be connected to and contiguous with the circuitry that connects the contact pads or studs in polymer section 62 and stud free sections 65 prior to removal of material from the regions 62 and 65 and prior to dicing on the wafer scale PSGA.

T is the region in the dicing paths or streets 30 where polymer 36 is molded thinner, or is totally removed, before dicing. Thus, a saw path could be confined to an area anywhere within the region T.

The wafer 5 may comprise Si, GaAs, etc., but a ceramic, or even a polymer, etc., may also be used. The wafer 5 supports the contact pads 77 and a copper conductor layer 40. The Cu conductor layer 40 covers the studs 25, over which are provided a Au/Ni coating.

A final plating process deposits a barrier layer 42 and an oxidation protection layer 45 of metal on the exposed Cu features. These metals are typically Ni and Au, respectively.

Variation in the process may be needed for different forms of final metal plating, where electrolytic Ni/Au would need a plating bus which would need to be removed, or where electroless Ni-immersion Au would not require a plating buss. Also, other metallization methods may be used, e.g. sputtering through a mechanical mask.

The resulting “packaged-wafer” may then be subjected to some form of testing, or testing and wafer level burn-in, or it may be diced up into individual components for subsequent testing, and possible burn-in as a packaged IC.

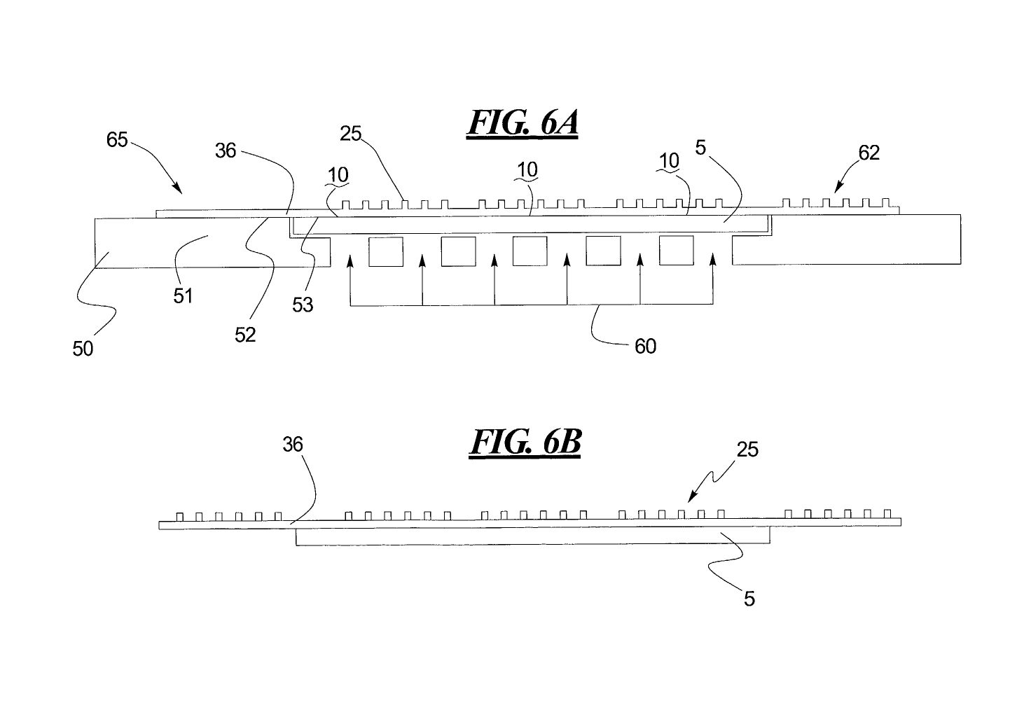

Another version of an exemplary aspect of the present invention for ISWA-PSGA wafer level testing and burn-in will now be discussed with reference to FIGS. 6A and 6B.

FIG. 6A shows a detailed schematic cross-sectional view of an in-situ polymer stud grid array after formation of a stud field.

The semiconductor wafer 5 of FIG. 1 is placed in a tooling plate 50, which provides an annular ring region 51 about the wafer 5. The annular ring region 51 is the circumferential region of tooling plate 50 immediately adjacent to the perimeter of the semiconductor wafer 5. One surface 52 of the annular ring region 51 is substantially co-planar with the surface 53 of the semiconductor wafer 5.

The wafer 5 and the desired portion of the surface of the tooling plate annular ring region 51 is coated with a polymer material 36 which is processed to form raised studs 25 across the surface of each IC device 10. The studs 25 may also be formed in the polymer section 62, that coats the desired surface of the annular ring region 51 of tooling plate 50, or the annular ring region 51 of tooling plate 50 may be left free of studs 25 in another polymer section 65.

For exemplary purposes FIGS. 6A and 6B exhibit extensions of the polymer coating 36 which extend beyond the perimeter of wafer 5 forming studded sections 62 and stud-free sections 65 While it is possible that cross section views such as those shown in FIGS. 6A and 6B could be made from an ISWS-PSGA that use studs in the polymer coating sections that extend beyond the perimeter of wafer 5. FIGS. 6A and 6B illustrate two possible wafer scale test and burn-in contact structures on the polymer coating sections that extend beyond the perimeter of wafer 5. In a finished, metallized ISWS-PSGA, metallized studs 121 on polymer section 62 would be used to make electrical contact for test and burn-in of the wafer. In a finished, metallized ISWS-PSGA, only metallized pads at the terminations of conductor patterns on polymer section 65, that link to metallized studs 121 across the surface of the wafer 5, would be used to make electrical contact for test and burn-in of the wafer.

Prior to coating, this polymer may be a solid, liquid, or a paste mixture of substantially solid phase(s) and substantially liquid phase(s).

The subsequent process steps are substantially the same as described after this point in the processing of the version 1 of the present invention. The key difference is the addition of the circuit region which extends beyond the edge of the wafer 5, the methods used and the resulting structures.

In this version of the invention, a circuit pattern now exists in the film material which is coating the surface of the annular ring region 51 about the wafer 5. The circuit elements in this annular ring region 51 are contiguous with desired circuit elements in the material which coats the surface of the wafer 5.

A polymer material 36 coats the wafer 5 and perimeter region 51 of the support tool 50. Studs 25 are formed on the wafer 5 in semiconductor device 10 locations, and test and burn-in contact studs or contact pads 77, on polymer sections 62 and 65, respectively, of the polymer film 36 are formed with a temporary bond to the support tool 50. Openings 60 in the supporting tool 50 facilitate removal of the studded wafer from the tool 50.

The wafer and the desired portion of the surface of the tooling plate annular ring region 51 is coated with a polymer material which is processed to form raised studs 25 across the surface of each IC device 10. The studs 25 may also be formed in the polymer which coats the desired surface of the annular ring region 51, section 62, or this region may be left stud-free, as in section 65.

Prior to coating, this polymer may be a solid, liquid, or a paste mixture of substantially sold phase(s) and substantially liquid phases(s).

The subsequent process steps are substantially the same as described after this point in the processing of the previous embodiment described above. The key difference is the addition of the circuit region which extends beyond the wafer edge, the method used, and the resulting structures.

In the present embodiment, a circuit pattern now exists in the film material which is coating the surface of the annular ring region 51 about the wafer 5. The circuit elements in this annular ring region 51 are contiguous with desired circuit elements in the material which coats the surface of the wafer 5.

The wafer 5, with the wafer scale PSGA layer, the annular extensions of the tester circuitry, and the support tooling 50 is now loaded into the tester for the wafer level test and possible wafer level burn-in. Afterwards, the tested wafer is separated from the tooling plate and the annular extension circuitry. The tooling plate 50 may be made of a high thermal conductivity material that could also provide a heat-sinking function, and the tooling plate 50 could also function as a voltage reference plane during testing and burn-in for improved frequency performance in the testing.

The circuit created on the annular film is designed to electrically connect to circuitry used in a wafer probe head connected to an IC tester. Through this connection, the entire wafer 5 is tested at operating frequency, or any other desired frequency that is supported by the equipment. Further, a similar connection can allow the wafer to be fully burned-in, if desired. This testing achieves Wafer Level Testing (WLT), or Wafer Level Test and Burn-In (WLBI). After this, it may be desirable to remove the circuit regions 62 or 65, which extend beyond the perimeter of the wafer 5. This may be performed in a number of methods including but not limited to excising with a laser, cutting with a mechanical blade, cutting with a water jet, cutting with a mechanical stamping tool, etc. Removal of this annular film circuit region will facilitate handling and reduce the complexity of the subsequent dicing step needed to singulate the individual packaged IC components. The wafer will then be processed to dice the individual IC devices 10 from the wafer 5. The IC devices 10 are then fully tested, or fully tested and burned-in, packaged integrated circuit components.

FIG. 6B shows a detailed schematic cross-sectional view of an in-situ polymer stud grid array after formation of a stud field and after removal from the wafer support tool 52.

The wafer test and burn-in may alternatively be conducted after removal from the tooling plate, leaving the annular film circuit region connected to the coated wafer. In either instance, the surface of the tooling plate may be coated with a material to facilitate the separation of the overlying circuit extensions form the tooling plate. All other aspects are the same as discussed above with respect to FIG. 6A.

After this, it may be desirable to remove the circuit regions 62 or 65, which extend beyond the perimeter of the wafer 5. This may be performed in a number of methods including but not limited to excising with a laser, cutting with a mechanical blade, cutting with a water jet, cutting with a mechanical stamping tool, etc. Removal of this annular film circuit region will facilitate handling and reduce the complexity of the subsequent dicing step needed to singulate the individual packaged IC components.

Although modifications and changes may be suggested by those skilled in the art to which this invention pertains, it is the intention of the inventors to embody within the patent warranted hereon all changes and modifications that may reasonably and properly come under the scope of their contribution to the art.

What is claimed is:

1. A method for forming an in-situ wafer scale polymer stud grid array, the method comprising:
providing a semiconductor wafer with integrated circuit device areas, the integrated circuit device areas having exposed bond pads and wafer passivation, and applying one or more metal film depositions over the bond pads and the wafer passivation;
patterning the one or more metal film depositions extending over the exposed bond pads and the wafer passivation to create metal film segments in desired locations over the bond pads to perform as bond pad cover metallurgy;
coating the semiconductor wafer with a first polymer layer processed to form raised studs having stud tip contacts in desired locations on the surface of each of the integrated circuit device areas;
removing regions of the first polymer layer to expose a central portion of underlying bond pad cover metallurgy;
processing the first polymer layer to clean and prepare the exposed central portion of the underlying bond pad cover metallurgy for adhesion to subsequently applied metal layers;
processing the first polymer layer for high conductor adhesion;
applying a metal coating to the semiconductor wafer to cover at least all exposed pad cover metallurgy areas and all exposed regions of the first polymer layer;
thickening the metal coating and forming an interconnect circuit thereon;
forming a second polymer layer over selected areas of the metal coating; and
depositing a barrier layer and an oxidation protection layer on exposed areas of the metal coating.

2. The method of claim 1, wherein the step of coating the semiconductor wafer with a first polymer layer comprises forming the first polymer layer to be thinner in regions between the integrated circuit device areas.

3. The method of claim 1, wherein the first polymer layer is removed in selected regions over the bond pad cover metallurgy and in regions between the integrated circuit device areas, by one of laser ablation, photolithography, reactive ion etching, or plasma etching.

4. The method of claim 1, further comprising roughening the bond pad cover metallurgy by one of chemical microetching or plasma microetching.

5. The method of claim 1, wherein coating the surface of the wafer with metal comprises one of sputtering, chemical vapor deposition, electroless plating, or a combination thereof.

6. The method of claim 1, wherein the step of thickening the metal coating comprises processing by electrolytic plating.

7. The method of claim 1, wherein the step of applying the second polymer layer excludes covering the stud tip contacts, saw path streets between the integrated circuit device areas and desired bond pads.

8. The method of claim 1, wherein the step of forming the second polymer layer comprises one of spin coating, spraying, dispensing or film lamination.

9. The method of claim 8, further comprising removing the second polymer layer from desired locations, by one of dry processing or wet processing.

10. The method of claim 1, wherein the step of metal plating comprises sputtering through a metal mask.

11. The method of claim 1, wherein the metal comprises copper.

12. The method of claim 1, wherein the pad cover metallurgy is formed by depositing electroless Ni to cover only the bond pads and the perimeter passivation area, and depositing a Au layer onto the Ni surface.

13. A method for forming an in-situ wafer scale polymer stud grid array on a semiconductor wafer having integrated circuit device areas, the integrated circuit device areas having patterned pad cover metallurgy regions, exposed bond pads and wafer passivation, the method comprising:
applying one or more metal film depositions over the exposed bond pads and the wafer passivation;
processing the one or more metal film depositions extending over the exposed bond pads and the wafer passivation across the semiconductor wafer to create metal film segments in desired locations over the exposed bond pads to perform as bond pad cover metallurgy;
placing the semiconductor wafer in a tooling plate which provides an annular ring region about the wafer, wherein one surface of the annular ring region is substantially coplanar with the surface of the wafer;
coating the semiconductor wafer and a desired portion of the surface of the tooling plate annular ring region with a first polymer layer processed to form raised studs at desired locations across the surface of each of the integrated circuit device areas;
removing regions of the first polymer layer to expose a central portion of underlying bond pad cover metallurgy;
processing the semiconductor wafer to clean and prepare the exposed central portion of the underlying bond pad cover metallurgy for adhesion to subsequently applied metal layers;
processing the first polymer layer for high conductor adhesion;
applying a metal coating over the semiconductor wafer and the annular ring region of the surrounding tooling plate surface covering at least all exposed pad cover metallurgy areas and all exposed regions of the first polymer layer;
coating the active surface of the semiconductor wafer with one or more metal films;
thickening the metal coating and forming an interconnect circuit thereon;
forming a second polymer layer over selected areas of the metal coating and selected regions of the exposed first polymer layer; and
depositing a barrier layer and an oxidation protection layer on exposed areas of the metal coating, and forming a circuit pattern about the semiconductor wafer that is contiguous with desired circuit elements in the metal coating across the active wafer surface and the annular ring region of the tooling plate.

14. The method of claim 13, wherein the step of coating the semiconductor wafer with a first polymer layer comprises forming the polymer coating to be thinner in regions between the integrated circuit device areas.

15. The method of claim 13, wherein the first polymer layer is removed in selected regions over the bond pad cover metallurgy and in regions between the integrated circuit device areas by one of laser ablation, photolithography, reactive ion etching, or plasma etching.

16. The method of claim 13, further comprising roughening the second phase metal deposition by one of chemical microetching or plasma microetching.

17. The method of claim 13, wherein the step of coating the surface of the semiconductor wafer with metal comprises one of sputtering, chemical vapor deposition or electroless plating, or a combination thereof.

18. The method of claim 13, wherein the step of thickening the metal coating comprises processing by electrolytic plating.

19. The method of claim 13, wherein the step of applying the second polymer layer excludes covering the stud tip contacts and the saw path streets between the integrated circuit device areas.

20. The method of claim 13, wherein the step of forming the second polymer layer comprises one of spin coating, spraying, dispensing or film lamination.

21. The method of claim 20, further comprising removing the polymer layer from the desired locations, by one of dry processing or wet processing.

22. The method of claim 13, wherein the step of metal plating comprises sputtering through a metal mask.

23. The method of claim 13, wherein the metal comprises copper.

24. The method of claim 13, wherein the pad cover metallurgy is formed by depositing electroless Ni to cover only the bond pads and the perimeter passivation area, and depositing a Au layer onto the Ni surface.

25. An in-situ wafer scale polymer stud grid array structure formed directly on a semiconductor wafer having individual integrated circuit device areas and connecting bond pads thereon, the polymer stud grid array structure comprising:
raised studs in desired locations formed across the surface of each of the integrated circuit device areas;
exposed bond pad cover metallurgy central portions;
one or more metal film depositions covering connecting the bond pads and the raised studs;
a metal layer covering the semiconductor wafer processed to connect desired pad cover metallurgy central portions with studs to form a desired interconnection circuit; and
a polymer layer covering the desired regions of the entire circuit area, such that a barrier layer and an oxidation protection layer of metal covers the exposed metal features, the grid array extending across the entire semiconductor wafer, and metallized studs being disposed across each of the integrated circuit device areas.

26. The structure of claim 25, where in the metal layer comprises copper.

27. An in-situ wafer scale polymer stud grid array structure comprising:
a semiconductor wafer having individual integrated circuit device areas and patterned pad cover metallurgy regions, and coated with a first polymer layer processed to form raised studs in desired locations across the surface of each of the integrated circuit device areas;
exposed bond pad cover metallurgy central portions;
a metal layer covering the semiconductor wafer process to connect desired pad cover metallurgy central portions with studs to form a desired interconnection circuit; and
a second polymer layer covering the entire interconnection circuit area, such that a barrier layer and an oxidation protection layer of metal covers the exposed metal features, the grid array field extends across the entire semiconductor wafer, and the metallized studs are disposed across each of the integrated circuit device areas, the circuit pattern in the film material coating the surface of the annular ring region about the semiconductor wafer is contiguous with desired circuit elements in the material coating the surface of the semiconductor wafer, and the interconnection circuit area extends beyond the edge of the semiconductor wafer.

28. The structure of claim 27, where in the metal layer comprises copper.
